(19) United States
(12) Patent Application Publication
(10) Pub. No.: US 2005/0199918 A1
(43) Pub. Date: Sep. 15, 2005

(54) Optimized trench power MOSFET with integrated schottky diode

(76) Inventors: Daniel Calafut, San Jose, CA (US); Christopher L. Rexer, Mountaintop, PA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/801,499

(22) Filed: Mar. 15, 2004

(51) Int. Cl. H01L 29/80

(52) U.S. Cl. 257/260

(57) ABSTRACT

In accordance with the present invention, a monolithically integrated structure combines a field effect transistor and a Schottky structure in an active area of a semiconductor substrate. The field effect transistor includes a first trench extending into the substrate and substantially filled by conductive material forming a gate electrode of the field effect transistor. A pair of doped source regions are positioned adjacent to and on opposite sides of the trench and inside a doped body region. The Schottky structure includes a pair of adjacent trenches extending into the substrate. Each of the pair of adjacent trenches is substantially filled by a conductive material which is separated from trench side-walls by a thin layer of dielectric. The Schottky structure consumes 2.5% to 5.0% of the active area, and the field effect transistor consumes the remaining portion of the active area.

### BACKGROUND OF THE INVENTION

The present invention relates in general to semiconductor power device technology, and in particular to a semiconductor power device with a trenched gate MOSFET and Schottky diode integrated in an optimum manner, and its method of manufacture. Emerging portable applications are driving semiconductor performance from many aspects. Power loss, switching frequency, current drive capability and cost are only few of the parameters that require optimization for a competitive mobile application. In the DC-DC conversion area, the switching losses associated with both the high-side and low-side transistors in the chopper stage require careful design to minimize power loss. Device characteristics such as series gate resistance, gate capacitance, blocking capability, and the on state resistance are important considerations in the device design.

Several approaches have been proposed for controlling the power losses. One approach tailors the lifetime profiles in the MOSFET by irradiation. This method requires special processing steps, and arriving at an optimal profile in practice while minimizing the penalty of adverse affects on other parameters can be a challenge in the sub-micron regime. A second approach has been adding an external Schottky diode in parallel with the MOSFET. The superior reverse recovery characteristics of the Schottky contact can improve the overall recovery of the integrated solution. The higher junction leakage of the Schottky interface is however a drawback. This has been slightly improved on by co-packaging the discrete Schottky diode with the discrete power MOSFET device. A drawback of the use of two discrete devices is the parasitic inductance encountered in connecting the Schottky diode to the MOSFET.

A third approach is to monolithically integrate the Schottky diode and the power MOSFET. This monolithic solution avoids issues with connection parasitics and allows considerably more flexibility in implementing the Schottky structure. Korman et al., for example, disclose in U.S. Pat. No. 5,111,253 a planar vertical double diffused MOSFET (DMOS) device with a Schottky barrier structure. A similar structure is described by Cogan in U.S. Pat. No. 4,811,065 where again a Schottky diode is monolithically integrated on the same silicon substrate as a lateral DMOS device. These devices, however, have been limited to planar power MOSFET technology. The monolithic Schottky diode structures used in these types of devices do not lend themselves well to power MOSFET devices using trench technology. A monolithic trenched gate MOSFET and MOS enhanced Schottky diode structure is disclosed by S. P. Sapp in the commonly assigned U.S. Pat. No. 5,111,253 incorporated herein by reference. Although this integrated trench power MOSFET has improved the overall performance of the trench MOSFET for particular applications, the full potential of this technology has not yet been realized.

There is therefore a need for an optimized monolithically integrated Schottky diode together with a trenched gate MOSFET device and methods of manufacture thereof.

### BRIEF SUMMARY OF THE INVENTION

In accordance with the present invention, a monolithically integrated structure combines a field effect transistor and a Schottky structure in an active area of a semiconductor substrate. The field effect transistor includes a first trench extending into the substrate and substantially filled by conductive material forming a gate electrode of the field effect transistor. A pair of doped source regions are positioned adjacent to and on opposite sides of the trench and inside a doped body region. The Schottky structure includes a pair of adjacent trenches extending into the substrate. Each of the pair of adjacent trenches is substantially filled by a conductive material which is separated from trench side-walls by a thin layer of dielectric. The Schottky structure further includes a Schottky diode having a barrier layer formed on the surface of the substrate and between the pair of adjacent trenches. The Schottky structure consumes 2.5% to 5.0% of the active area, and the field effect transistor consumes the remaining portion of the active area.

In one embodiment, the field effect transistor further includes a metal layer contacting the pair of doped source regions. The metal layer and the barrier layer comprise one of either titanium tungsten or titanium nitride.

In another embodiment, the barrier layer and the metal layer contacting the source regions connect together by an overlying layer of metal.

In another embodiment, the barrier layer forms the Schottky diode anode terminal and the substrate forms the Schottky diode cathode terminal.

### BRIEF DESCRIPTION OF THE DRAWINGS

FIG. 1 shows a cross-sectional view of a simplified example of an integrated trench MOSFET-Schottky diode structure;

FIG. 2 shows a simplified top view of the embodiment shown in FIG. 1;

FIG. 3 shows an alternate embodiment wherein the polysilicon layers filling the trenches are recessed;

FIGS. 4A and 4B show yet other embodiments wherein each trench structure includes one or more electrodes buried under the gate electrode;

FIG. 5 shows the simulation circuit for the diode recovery analysis along with an example waveform for modeling the diode recovery;

FIG. 6 shows the MOSFET-Schottky structure used in the simulation modeling;

FIG. 7 shows the circuit and driving waveforms used in simulating the switching losses in a DC-DC converter;

FIG. 8 shows the simulation results for the power loss versus percentage area of the Schottky structure for the converter high-side switch, the low-side switch, as well as their sum;

FIG. 9 shows the waveforms for the drain leakage and the forward voltage drop versus the percentage of the Schottky structure area;

FIG. 10 shows silicon results along with the simulated values for the reverse recovery charge (Qrr) versus percentage of the Schottky structure area;

FIG. 11 shows the normalized efficiency versus output current for the low-side switch;

FIG. 12 shows the low-side switch turnoff-recovery waveform for 3 different Schottky structure contributions;

FIG. 13 shows the on state conduction waveform for the low-side switch;

FIG. 14 shows a detailed view of the MOSFET-Schottky structure sub-circuit shown in FIG. 5; and

FIG. 15 shows the normalized gate displacement current during the device recovery for the cases of the 2.5% and 50% Schottky structure contribution.

### DETAILED DESCRIPTION OF THE INVENTION

In accordance with the present invention a trench power MOSFET includes a Schottky structure which consumes about 2.5% to 5% of the total active area while the field effect transistor consumes the remaining portion of the active area. It has been discovered that this results in the most optimum device efficiency. In one particular application, the loss contribution of the low-side switch of a DC-DC converter is substantially reduced when the power MOSFET device of the present invention is used as the low-side switch. The phrases “Schottky structure” and “trench MOS barrier Schottky (TMBS)” are used interchangeably in the specification and the drawings.

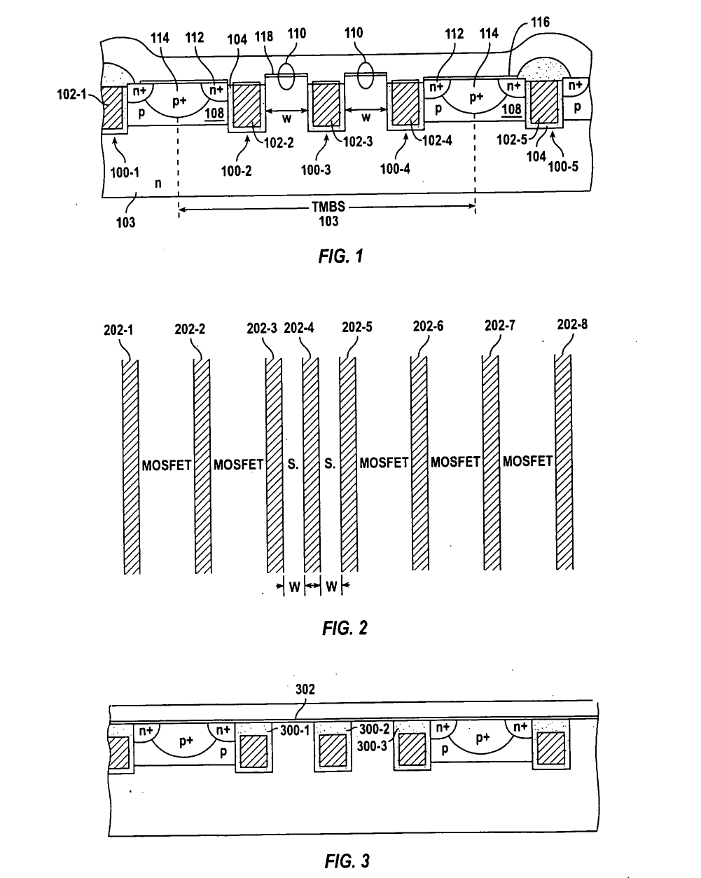

FIG. 1 shows a cross-sectional view of a simplified example of an integrated trench MOSFET-Schottky diode structure fabricated on a silicon substrate 103. A plurality of trenches 100 are patterned and etched into substrate 103. Substrate 103 may comprise an upper n-type epitaxial layer (not shown). A thin dielectric layer 104 (e.g., silicon dioxide) is formed along the side-walls of trenches 100, after which conductive material 102 such as polysilicon is deposited to substantially fill each trench 100. A p-type well 108 is then formed between trenches 100 except between those trenches (e.g., 100-2 and 100-4) where Schottky diodes are to be formed. Thus, regions between trenches 100-2 and 100-4 where Schottky diodes are to be formed are masked during the p-well implant step. N+source junctions 112 are then formed inside p-well regions 108, either before or after the formation of p+heavy body regions 114. A layer of conductive material 116 such as titanium tungsten (TiW) or titanium nitride (TiNi) is then patterned and deposited on the surface of the substrate to make contact to n+source junctions 112. The same material is used in the same step to form anode 118 of Schottky diode 110. Metal (e.g., aluminum) is then deposited on top to separately contact MOSFET source regions 112 as well as p+heavy body 114 and Schottky anode 118.

As can be seen, the MOS trench Schottky structure requires no new processing steps since it is a standard unit step in the MOSFET process flow. A preferred process for the trench MOSFET of the type shown in the exemplary embodiment of FIG. 1, is described in greater detail in commonly-assigned U.S. Pat. No. 6,429,481, titled “Field Effect Transistor and Method of its Manufacture, ” by Mo et al., which is hereby incorporated by reference in its entirety. It is to be understood, however, that the teachings of the present invention apply to other types of trench processes with, for example, different body structures or trench depths, different polarity implants, closed or open cell structures.

The resulting structure, as shown in FIG. 1, includes Schottky diodes 110 that are formed between trenches 100-2 and 100-4 surrounded by trench MOSFET devices on either side. N-type substrate 103 forms the cathode terminal of Schottky diodes 310 as well as the drain terminal of the trench MOSFET. Conductive layer 118 provides the diode anode terminal that connects to the source terminal of the trench MOSFET. In this embodiment, the polysilicon in trenches 100-2, 100-3 and 100-4 connects to the gate polysilicon (100-1 and 100-5) of the trench MOSFET and is therefore similarly driven. The Schottky diode as thus formed has several operational advantages. As voltage builds on the cathode of the Schottky diode (i.e., substrate 103), the MOS structure formed by the poly-filled trenches 100-2, 100-3, and 100-4 forms a depletion region. This helps reduce the diode leakage current. Furthermore, the distance W between trenches 100-2 and 100-3, and between trenches 100-3 and 100-4 can be adjusted such that the growing depletion regions around adjacent trenches 100-2 and 100-3, and 100-3 and 100-4 overlap in the middle. This pinches off the drift region between Schottky barrier 118 and the underlying substrate 103. The net effect is a significant increase in the reverse voltage capability of the Schottky diode with little or no detrimental impact on its forward conduction capability.

In one embodiment, the distance W, or the width of the mesa wherein the Schottky diode is formed, is smaller than inter-trench spacing for MOSFETs. The distance W can be, for example, 0.5 μm depending on the doping in the drift region and the gate oxide thickness. The second variation is in the number of adjacent trenches used to form the Schottky diodes 110. Although FIG. 1 shows two parallel Schottky diode mesas 110 are formed between three trenches 102-2, 102-3, and 102-4, the invention is not limited as such. As is described further below, to the extent that the ratio of the total area of the trench Schottky structure to the total MOSFET area is maintained within a predetermined range, the specific number of trenches (e.g., 3 in FIG. 1) in the Schottky structures is arbitrary. FIG. 2 provides a simplified top view of the embodiment shown in FIG. 1. In this drawing, an exemplary open-cell trench MOSFET process is assumed where trenches extend in parallel. Eight trenches 202-1 to 202-8 where a double-mesa Schottky diode is formed between trenches 202-3, 202-4, and 202-5 are shown. The distance W between the Schottky trenches is smaller than the other inter-trench spacings.

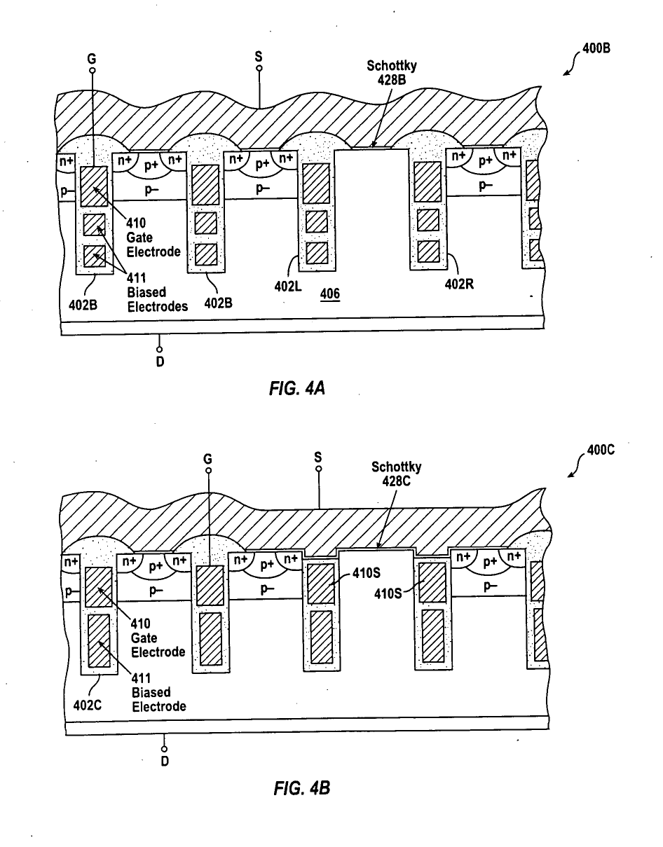

The present invention is not limited to the particular trench structure shown in FIG. 1. For example, in an alternate embodiment shown in FIG. 3, the polysilicon layers filling the trenches are recessed and covered by a dielectric layer (e.g., oxide) 300. Thus, when the Schottky anode/MOSFET source metal layer 302 is deposited, the polysilicon layers in the trenches of the Schottky structure remain isolated. The polysilicon layers in the trenches of the Schottky structure can thus float or connect to the gate poly inside the MOSFET trenches. In other embodiments, each trench structure includes electrodes buried under a gate electrode as shown in FIGS. 4A and 4B. In FIG. 4A, MOSFET 400B includes active trenches 402B each having electrodes 411 buried under a gate electrode 410. A Schottky diode 428B is formed between two trenches 402L and 402R as shown. The charge balancing effect of biased electrodes 411 allows for increasing the doping concentration of the drift region without compromising the reverse blocking voltage. Higher doping concentration in the drift region in turn reduces the forward voltage drop for this structure. The depth of each trench as well as the number of the buried electrodes may vary. In the FIG. 4C variation, trench 402C has only one buried electrode 411, and gate electrodes 410S in the trenches flanking Schottky diode 428C connect to the source electrode as shown. Gate electrodes 410S can alternatively connect to the gate terminal of the MOSFET. In yet another embodiment, the oxide thickness along the bottom of the trenches is made thicker than that along the trench sidewalls to advantageously reduce the gate to drain capacitance.

The inventors have discovered, based on the simulation results as well as silicon data, that there is an optimum contribution of the Schottky structure area which maximizes the performance of the integrated device. More specifically, it has been discovered that a ratio of the total area of the Schottky structure to the total area of the MOSFET in the range of 2.5% to 5% results in optimum performance. In an exemplary embodiment wherein the MOSFET cell pitch is 2.5 μm and the pitch of a Schottky structure or a TMBS cell is 5 μm, a 2.5% ratio is obtained by forming one TMBS cell every 40 MOSFET cells.

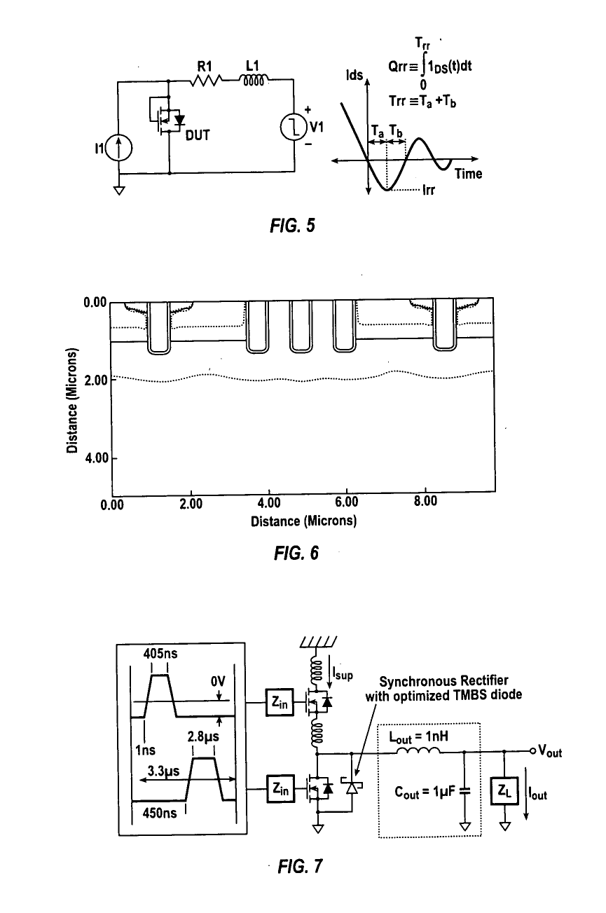

The silicon data was obtained form an integrated Schottky structure built on a 0.35 μm trench DMOS baseline process flow. The trench depth is 11 μm and the gate oxide is 400A. The starting material is 0.25 Ohm-cm and the Schottky interface used is Titanium with a work function of 4.3 eV. These values are merely illustrative and not intended to be limiting. The simulation data was obtained using device simulator Medici. The mixed-mode circuit-device capability of Medici, combining finite element device models with nodal analysis of SPICE, is well suited for the intended device and circuit simulations. The simulation circuit for the diode recovery along with an example waveform for modeling diode recovery are shown in FIG. 5. The MOSFET-Schottky structure used in the modeling is shown FIG. 6.

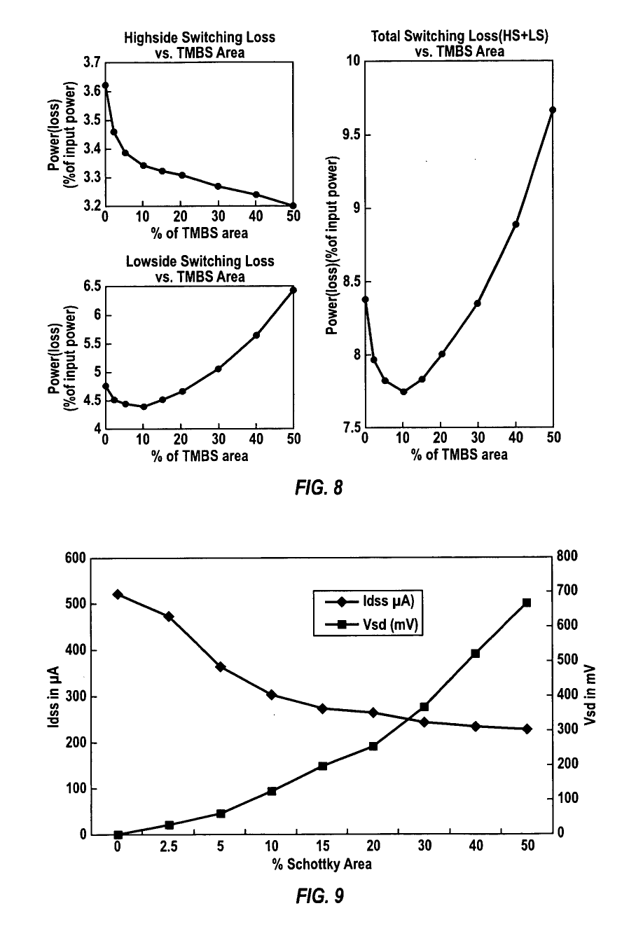

In both the simulations and the silicon experiments, the ratio of the total Schottky structure area to that of the MOSFET was the independent variable ranging from 0% to 50%. The stored charge (Qrr) results for both simulation and bench data are discussed further below. As the results show, Qrr values display a well defined minimum with values rising rapidly as the total Schottky structure area is increased. Based on this data, it was projected that the increase in Qrr would translate to higher losses in the DC-DC converter application. The circuit and driving waveforms used in the converter are shown in FIG. 7. Power loss in the circuit was calculated by averaging the current-voltage product waveform of the high and low side switches and dividing by the total input power. The simulation results for both switches, as well as their sum, are shown in FIG. 8.

Laboratory measurements were performed on both device and circuit levels. In FIG. 9, waveforms for the drain leakage (i.e., the off-state leakage) and the forward voltage drop versus the percentage of the Schottky structure area are shown. As can be seen, as the percentage of the Schottky structure area increases from 0% to about 15%, the forward voltage drops relatively rapidly from that of the pn junction diode (about 530mV) to that of the Schottky barrier diode, and then starts to level off. The off state leakage also tracks the increase in the percentage of the Schottky structure area, but not quite in a linear fashion.

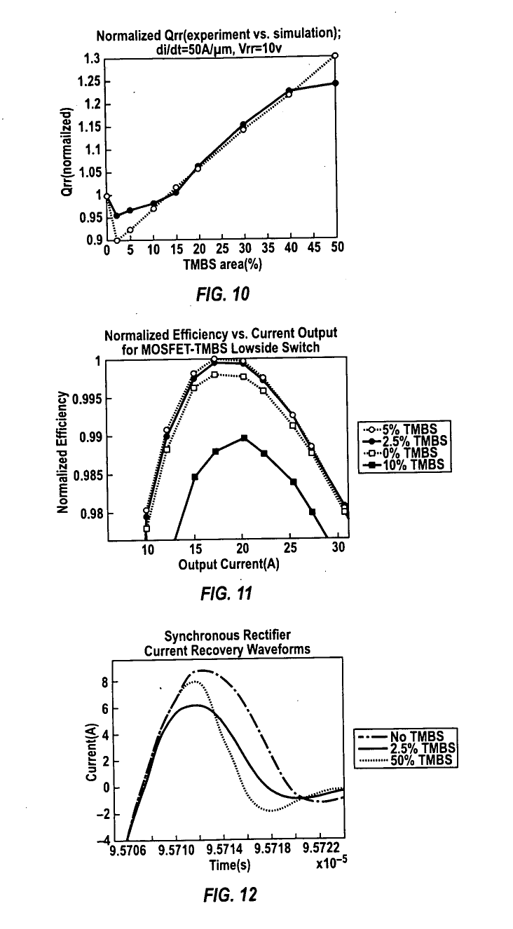

For the reverse recovery characteristics, the Qrr silicon results along with the simulated values are shown in FIG. 10. The Qrr waveform in FIG. 10 shows a minimum point at about 2.5% Schottky structure contribution and rises rapidly with increasing Schottky structure area. For the circuit measurements, a two phase DC-DC converter circuit was used to study the efficiency versus output current for the various contributions of Schottky structure. The high-side switching device was chosen from the same trench technology, but optimized for this location in the circuit. The normalized efficiency results of these tests are shown in FIG. 11. This result indicates that the low-side switch with 2.5% Schottky has the highest value (compared to other Schottky structure contribution percentages) at the maximum of the efficiency curves.

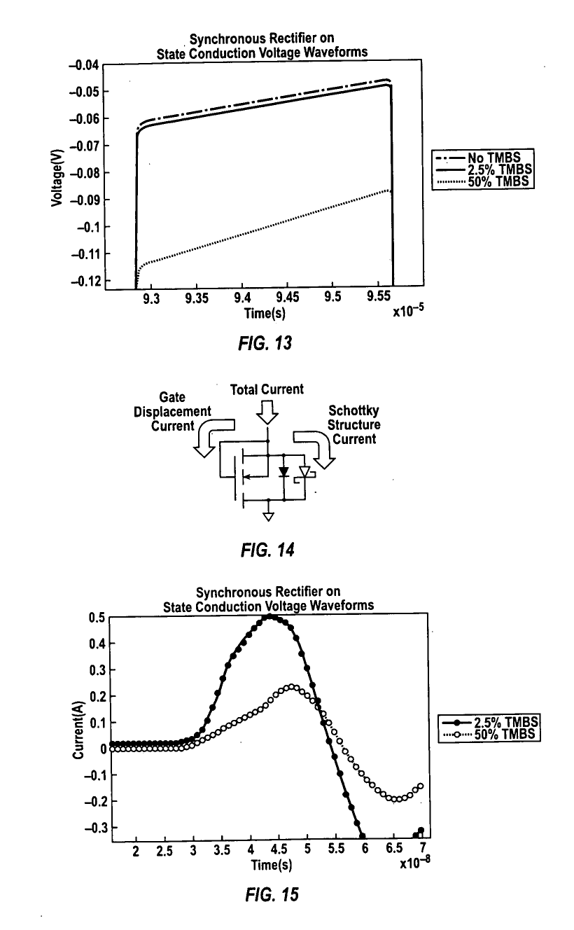

As can be seen from FIGS. 10 and 11, the Qrr silicon results track the predictions of the device model, and the efficiency results could be equally well inferred from the power loss simulation results shown in FIG. 8. Upon close examination of the converter waveforms, it can be seen that the increased power loss and hence lowering of efficiency can not be correlated with the detailed switching waveforms of the converter. FIG. 12 shows the low-side switch turnoff-recovery waveform for 3 different Schottky structure contributions (0%, 2.5%, and 50%). These results clearly show that any Schottky structure contribution between 0% and 50% gives improved low-side recovery characteristics and hence lower over all power loss, so the collective top level observations did not agree with the more detailed view of the waveform behavior. This apparent discrepancy is resolved by examining the on state or conduction portion of the waveform of the low-side switch shown in FIG. 13. As can be seen, the voltage drop across the low-side switch for the 50% Schottky structure is nearly double that of the zero Schottky structure, and since the duty cycle for the low-side drive waveform is more than 50% in this work, the conduction losses are sensitive to any changes in the on-state resistance of the device. This however, did not explain the reverse recovery waveform behavior versus increasing Schottky structure ratio results in FIG. 10. This required detailed examination of the current distribution of the hole and electrons in both the MOSFET and Schottky structure portions of the device, particularly the gate terminal of the device.

FIG. 14 shows a detailed view of the MOSFET-Schottky structure sub-circuit shown in FIG. 5. Various current components are identified in FIG. 14. FIG. 15 shows the normalized gate displacement current during the device recovery for the cases of the 2.5% and 50% Schottky structure contribution. As show, the maximum current contribution of the gate terminal represents approximately half of the maximum total recovery current for the 2.5% Schottky structure contribution. In the case of 50% contribution, the gate current makes up about 20% of the maximum current. This current is due to the gate-drain capacitance in the MOSFET and is thus a displacement current which is injected into the total recovery value as a consequence of the testing circuit configuration shown in FIG. 5.

Two key observations relating to the device and circuit behavior can be made. The data shows that parasitic gate capacitance can have a major role in determining diode recovery characteristics, particularly at low levels of Schottky structure contribution. This may not, however, form a reliable projection of circuit behavior in applications where the MOSFET gate is driven independently, as in the important case of synchronous rectification. The second observation is that the current recovery waveforms in FIG. 12 show that all contributions of Schottky structure, up to 50%, have improved switching characteristics over the MOSFET-only solution. The influence of the capacitance of the Schottky structure would be large for cases where it makes up 50% of the total active area, and managing these parasitic elements can lead to improved recovery characteristics.

Accordingly, the present invention provides methods and structure for an optimized monolithically integrated Schottky diode and trench MOSFET. By distributing a Schottky diode within the cell array of the trench MOSFET so that the ratio of the Schottky structure area to the MOSFET area is in the range of 2.5% to 5%, the overall device efficiency is improved. While the above is a complete description of specific embodiments of the present invention, it is possible to use various alternatives, modifications and equivalents. For example, the techniques taught by the present invention can be employed in trench processes using either an open-call or a closed-cell structure. Therefore, the scope of the present invention should be determined not with reference to the above description but should, instead, be determined with reference to the appended claims, along with their full scope of equivalents.

1. A monolithically integrated structure combining a field effect transistor and a Schottky structure in an active area of a semiconductor substrate, wherein:
the field effect transistor comprises:
a first trench extending into the substrate and substantially filled by conductive material forming a gate electrode of the field effect transistor; and
a pair of doped source regions positioned adjacent to and on opposite sides of the trench and inside a doped body region, the doped source regions forming a source electrode of the field effect transistor, and the substrate forming a drain electrode of the field effect transistor, and
the Schottky structure comprises:
a pair of adjacent trenches extending into the substrate, the pair of adjacent trenches being substantially filled by conductive material which is separated from trench side-walls by a thin layer of dielectric; and
a Schottky diode having a barrier layer formed on the surface of the substrate and between the pair of adjacent trenches;
wherein the Schottky structure consumes 2.5% to 5.0% of the active area, and the field effect transistor consumes the remaining portion of the active area.

2. The monolithically integrated structure of claim 1 wherein the field effect transistor further comprises a metal layer contacting the pair of doped source regions, the metal layer and the barrier layer comprise one of either titanium tungsten or titanium nitride.

3. The monolithically integrated structure of claim 2 wherein the barrier layer and the metal layer contacting the source regions connect together by an overlying layer of metal.

4. The monolithically integrated structure of claim 1 wherein the barrier layer forms the Schottky diode anode terminal and the substrate forms the Schottky diode cathode terminal.

5. The monolithically integrated structure of claim 1 wherein the integrated structure further comprises a second trench adjacent to the first trench, the second trench forming the gate electrode of the field effect transistor in a similar fashion to the first trench, wherein a distance between the first trench and the second trench is greater than a distance W separating the pair of adjacent trenches, and wherein the barrier layer and a metal layer contacting the source regions of the field effect transistor comprise one of either titanium tungsten or titanium nitride.

6. The monolithically integrated structure of claim 1 wherein the conductive material in the first and second trenches electrically connects to the conductive material in the pair of adjacent trenches between which the Schottky diode is formed.

7. The monolithically integrated structure of claim 1 wherein the conductive material in the pair of adjacent trenches between which the Schottky diode is formed is electrically isolated from the conductive material in the first and second trenches.

8. The monolithically integrated structure of claim 1 wherein the conductive material in the pair of adjacent trenches between which the Schottky diode is formed, is recessed into the pair of adjacent trenches and covered by a layer of dielectric material.

9. The monolithically integrated structure of claim 1 wherein the first trench has a thicker insulating layer along its bottom than along its sidewalls.

10. The monolithically integrated structure of claim 1 wherein each of the pair of adjacent trenches and the first trench has a thicker dielectric layer along its bottom than along its sidewalls.

11. A method of manufacturing a trench field effect transistor and a Schottky structure in an active area of a semiconductor substrate, the method comprising:
forming a plurality of trenches extending into the substrate, with a first trench being adjacent to a second trench, and the second being adjacent to a third trench, wherein the first trench forms part of the field effect transistor and the second and third trenches form part of the Schottky diode structure;
forming a layer of conductive material inside the plurality of trenches, the layer of conductive material being insulated from trench walls by a dielectric layer;
forming a doped body region extending into the substrate between the first and the second trenches and not between the second and the third trenches;
forming a doped source region inside the doped body region and adjacent to a side wall of the first trench; and
forming a conductive anode layer on the surface of the substrate between the second and the third trenches, and also between the first and second trenches,
whereby an interspersed field effect transistor-Schottky structure is formed in the active area such that the Schottky structure consumes 2.5% to 5.0% of the active area, and the field effect transistor consumes the remaining portion of the active area, and
wherein the substrate provides a drain terminal, the doped source region provides a source terminal and the conductive layer in the first trench provides a gate terminal, and a Schottky diode is formed with the substrate providing a cathode terminal and the conductive anode layer providing an anode terminal.
